(19) United States
(12) Patent Application Publication
(10) Pub. No.: US 2012/0236649 A1
(43) Pub. Date: Sep. 20, 2012

(54) HOT CARRIER PROGRAMMING OF NAND FLASH MEMORY

(75) Inventors: Shaw-Hung Ku, Taipei (TW); I-Chen Yang, Changhua (TW)

(73) Assignee: MACRONIX INTERNATIONAL CO., LTD., Hsinchu (TW)

(21) Appl. No.: 13/050,658

(22) Filed: Mar. 17, 2011

(51) Int. Cl. G11C 16/10

(52) U.S. Cl. 365/185.18

(57) ABSTRACT

A NAND memory device includes strings of NAND memory cells, where each memory cell includes a charge trapping structure formed over a lightly-doped substrate region. A selected one of the NAND memory cells can be programmed by application of a relatively low program voltage in combination with a previously-applied set-up voltage, which is applied to the substrate for initiating inversion. The inversion in the substrate causes electrons to become hot in the channel regions, including the channel of the selected memory cell. As a result, the relatively lower program voltage can be used at the control gate of the selected memory cell for sufficiently energizing hot electrons to tunnel into the charge trapping structure of the selected memory cell.

### RELATED APPLICATIONS

The present application is related to co-pending U.S. patent application Ser. No. 12/797,994 entitled Hot Carrier Programming in NAND Flash, filed on Jun. 10, 2010 and the co-pending application entitled Low Voltage Programming in NAND Flash, invented by Ping-Hung Tsai, Jyun-Siang Huang and Wen-Jer Tsai, Attorney Docket No. MXIC 1952-1 (P990092US) the contents of which are incorporated herein by reference as if set forth in full.

### BACKGROUND

1. Technical Field

The present application relates to flash memory technology, and more particularly to flash memory suitable for low voltage program and erase in a NAND configuration.

2. Related Art

Flash memory is a class of non-volatile integrated circuit memory technology. Traditional flash memory employs floating gate memory cells. As the density increases in memory devices, and the floating gate memory cells get closer and closer together, interference between the charge stored in adjacent floating gates becomes a problem. This is limiting the ability to increase the density of flash memory based on floating gate memory cells. Another type of memory cell used for flash memory can be referred to as a charge trapping memory cell, which uses a dielectric charge trapping layer in place of the floating gate. Charge trapping memory cells use dielectric charge trapping material that does not cause cell-to-cell interference like that encountered with floating gate technology, and is expected to be applied for higher density flash memory.

The typical flash memory cell includes a field effect transistor FET structure having a source and drain separated by a channel, and a gate separated from the channel by a charge storage structure including a tunnel dielectric layer, the charge storage layer (floating gate or dielectric), and a blocking dielectric layer. According to the early conventional charge trapping memory designs referred to as SONOS devices, the source, drain and channel are formed in a silicon substrate (S), the tunnel dielectric layer is formed of silicon oxide (O), the charge storage layer is formed of silicon nitride (N), the blocking dielectric layer is formed of silicon oxide (O), and the gate comprises polysilicon (S).

Flash memory devices generally are implemented using NAND or NOR architectures, although others are known, including AND architectures. The NAND architecture is popular for its high density and high speed when applied to data storage applications. The NOR architecture is better suited to other applications, such as code storage, where random byte access is important. In a NAND architecture, the programming processes typically rely on Fowler-Nordheim (FN) tunneling, and require high voltages, such as on the order of 20 Volts, and require high voltage transistors to handle them. The addition of high voltage transistors on integrated circuits, in combination with transistors used for logic and other data flow, introduces complexity in the manufacturing processes. This increased complexity in turn increases the costs of the devices.

Accordingly, it is desirable to provide a new memory technology suitable for low voltage programming operations, and which is configurable in a NAND architecture.

### SUMMARY

Memory devices and methods associated with memory devices are described herein. According to one aspect of the present disclosure, a memory device can comprising a plurality of memory cells arranged in series in a semiconductor body, a plurality of word lines, each word line in the plurality of word lines being coupled to a respective one of the plurality of memory cells, and control circuitry coupled to the plurality of word lines. The control circuitry can be adapted for programming a selected memory cell in the plurality of memory cells corresponding to a selected word line. The programming can be accomplished by biasing one of first and second ends of the plurality of memory cells to a set-up voltage, reducing the voltage level being applied to the one of the first and second ends of the plurality of memory cells from the set-up voltage to a bit-line programming voltage, applying a pass voltage to word lines corresponding to unselected memory cells, and applying a program voltage to the selected word line corresponding to the selected memory cell.

The semiconductor body can include a lightly doped substrate region. The doping concentration of the lightly doped substrate can be in a range that is less than or equal to 5×10¹² cm⁻². The lightly doped substrate region can include an N-type doped region.

Each memory cell can comprise a respective one of a plurality of charge trapping structures. The charge trapping structures can be formed over a lightly doped substrate region. The charge trapping structures can include respective tunnel dielectric layers each having a thickness that is less than 90 Angstroms.

The program voltage applied to the selected word line can be less than or equal to 17 Volts. The pass voltage can be in a range of 3 Volts to 8 Volts.

The application of the set-up voltage can cause inversion in the semiconductor body.

The biasing of one of first and second ends can be performed during a first time period, and the reducing of the voltage level, applying of the pass voltage, and applying of the program voltage can be performed during a second time period following the first time period.

The biasing of one of first and second ends can be performed while applying a ground level voltage to another of the first and second ends and to each of the plurality of word lines.

According to another aspect of the present disclosure, a memory device comprises a first string of memory cells arranged in series in a semiconductor body, a second string of memory cells arranged in series in the semiconductor body, a plurality of word lines, each word line in the plurality of word lines being coupled to a respective one of the first string of memory cells and to a respective one of the second string of memory cells, and control circuitry coupled to the plurality of word lines. The control circuitry can be adapted for programming a selected memory cell in the first string of memory cells corresponding to a selected word line. The programming can be accomplished by applying a bit-line programming voltage to one of first and second ends of the first string of memory cells, maintaining first and second ends of the second string of memory cells at a ground level voltage, applying a pass voltage to word lines corresponding to unselected memory cells, and applying a program voltage to the selected word line corresponding to the selected memory cell.

The semiconductor body can include a lightly doped substrate region. The doping concentration of the lightly doped substrate can be in a range that is less than or equal to 5×10¹² cm⁻². The lightly doped substrate region can include an N-type doped region.

Each memory cell can comprise a respective one of a plurality of charge trapping structures. The charge trapping structures can be formed over a lightly doped substrate region. The charge trapping structures can include respective tunnel dielectric layers each having a thickness that is less than 90 Angstroms.

The program voltage applied to the selected word line can be less than or equal to 17 Volts. The pass voltage can be in a range of 3 Volts to 8 Volts.

The application of the set-up voltage can cause inversion in the semiconductor body.

The control circuitry can further be configured for, during a first time period, biasing the one of first and second ends of the first string of memory cells to a set-up voltage, while applying the ground level voltage to another of the first and second ends, to each of the plurality of word lines, and to both of the first and second ends of the second string of memory cells. The applying of the bit-line programming voltage, the maintaining of the first and second ends at the ground level voltage, the applying of the pass voltage, and the applying of the program voltage can all be performed during a second time period following the first time period.

The applying of the bit-line programming voltage can include reducing the voltage level being applied to the one of the first and second ends of the first string of memory cells from the set-up voltage to the bit-line programming voltage.

### BRIEF DESCRIPTION OF THE DRAWINGS

Features, aspects, and embodiments of the inventions are described in conjunction with the attached drawings, in which:

FIGS. 1A and 1B show simplified cross-sectional views of a selected NAND string and an unselected NAND string, respectively, which are biased according to typical programming techniques;

FIG. 1C shows a schematic view of the NAND strings shown in FIGS. 1A and 1B;

FIG. 2A shows a simplified cross-sectional view of a portion of a NAND flash memory string according to the present disclosure;

FIG. 2B shows a schematic view of the NAND flash memory strings in accordance with an embodiment of the present disclosure;

FIG. 3 shows a signal diagram of signals used in a programming operation for the memory cell strings shown in FIGS. 2A and 2B;

FIGS. 4A and 4B show charts illustrating examples of programming voltages and tunneling oxide thicknesses that can be used for specific implementations of the device shown in FIGS. 2A and 2B;

FIG. 5 shows a comparison of the WL0 disturbance for a conventional NAND memory string compared to that of the present memory device;

FIG. 6 shows an energy band diagram illustrating how the hot carrier injection occurs during the presently disclosed programming operation;

FIG. 7 shows exemplary threshold voltages V_{T} for the programmed and erased memory cells of the present disclosure; and

FIG. 8 shows a simplified block diagram of an integrated circuit employing the hot carrier injection programmed NAND flash as described herein.

### DETAILED DESCRIPTION

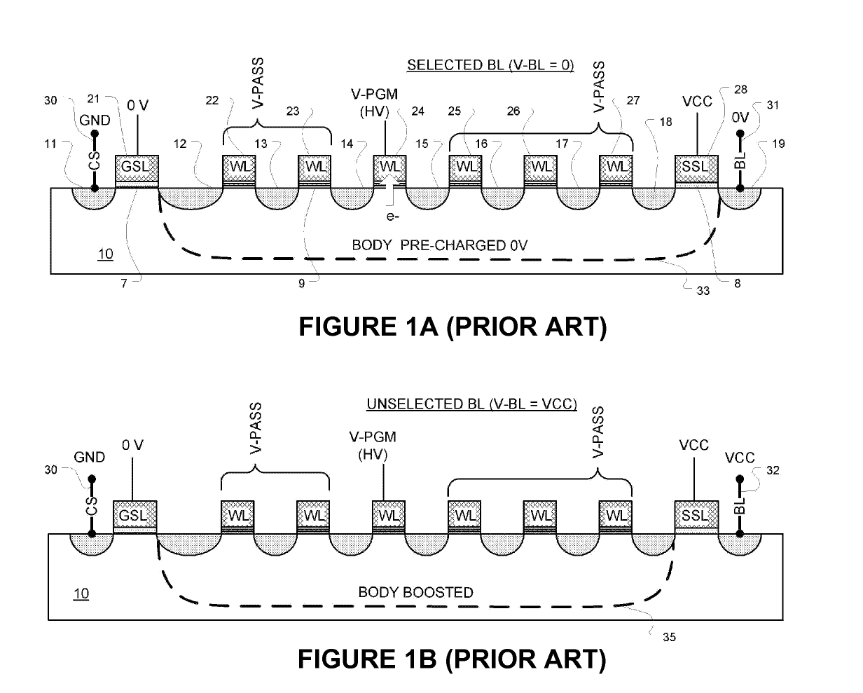

A detailed description of embodiments of the present application is provided with reference to the FIGS. 1-8.

FIGS. 1A and 1B show in cross-section a plurality of dielectric charge trapping flash memory cells arranged in series to form a NAND string and biased for FN tunneling programming, as is typical in NAND architecture flash memory. FIG. 1C shows a schematic view of the NAND strings shown in FIGS. 1A and 1B.

FIG. 1A shows the biasing for a NAND string that includes a target cell (cell A in FIG. 1C) on a selected bit line, while FIG. 1B shows the biasing for a NAND string on an unselected bit line. One technology for implementation of NAND flash using bandgap engineered SONOS (BE-SONOS) charge trapping technology is described in U.S. Pat. No. 7,315,474 by Lue, which is incorporated by reference as if fully set forth herein. NAND strings can be implemented in a variety of configurations, including finFET technology, shallow trench isolation technology, vertical NAND technology and others. See, for an example vertical NAND structures, European Patent Application No. EP 2 048 709 by Kim et al. entitled “Non-volatile memory device, method of operating same and method of fabricating the same.”

Referring to FIG. 1A, the memory cells are formed in a semiconductor body 10. For n-channel memory cells, the semiconductor body 10 can be an isolated p-well, within a deeper n-well in a semiconductor chip. Alternatively, the semiconductor body 10 can be isolated by an insulating layer or otherwise. Some embodiments may employ p-channel memory cells in which the doping for the semiconductor body would be n-type.

The plurality of flash memory cells is arranged in a string extending in a bit line direction, orthogonal to word lines. Word lines 22-27 extend across a number of parallel NAND strings. Terminals 12-18 are formed by n-type regions (for n-channel devices) in the semiconductor body 10, and act as the source/drain regions for the memory cells. A first switch, which is formed by a MOS transistor having a gate in a ground select line GSL 21, is connected between the memory cell corresponding with first word line 22 (WL0 in FIG. 1C) and a contact 11 formed by an n-type region in the semiconductor body 10. The contact 11 is connected to common source CS line 30. A second switch, which is formed by a MOS transistor having a gate in a string select line SSL 28, is connected between the memory cell corresponding to the last word line 27 and a contact 19 formed by an n-type region in the semiconductor body 10. The contact 19 is connected to a bit line BL 31. The first and second switches in the illustrated embodiment are MOS transistors, having gate dielectrics 7 and 8 formed by, for example, silicon dioxide.

In this illustration, there are six memory cells in the string for simplicity. In typical implementations, a NAND string may comprise 16, 32, or more memory cells arranged in series. The memory cells corresponding to the word lines 22-27 have charge trapping structures 9 between the word lines and channel regions in the semiconductor body 10. The charge trapping structures 9 in the memory cells can be dielectric charge trapping structures, floating gate charge trapping structures, or other flash memory structures suitable for programming using techniques described herein. Also, embodiments of NAND flash structures have been developed which are junction-free, where the terminals 13-17, and optionally terminals 12 and 18, may be omitted from the structure.

FIG. 1A shows the biasing according to a typical prior art technology to induce FN tunneling to program the memory cell corresponding with word line 24. According to the biasing illustrated, the GSL is biased to about zero Volts while the CS line is grounded, so that the first switch corresponding to the GSL line 21 is off. The SSL is biased to about VCC while the selected bit line BL 31 is grounded, so that the second switch corresponding to the SSL line 28 is on. Under these conditions, the semiconductor body in the region 33 associated with the NAND string is pre-charged to about 0 Volts. The selected word line 24 is biased at a high-voltage programming level V-PGM, which can be on the order of 20-22 Volts in some embodiments. This high voltage is selected to be sufficient for causing hot electrons in the body 10 to tunnel into the charge trapping structure 9 of the selected memory cell. Meanwhile, the unselected word lines 22, 23, and 25-27 are biased to a program-disturb pass voltage V-PASS, which is less than V-PMG by an amount that is sufficient to inhibit programming in unselected memory cells in the string. For example, the gate of memory cell C receives the pass voltage V-PASS from word line 25, and although the memory cell C has a body region that is set for programming, the V-PASS voltage is low enough to disturb the programming procedure for memory cell C.

FIG. 1B shows the biasing according to prior art technology at unselected bit lines for NAND strings that share the word lines 22-27 with the selected string shown in FIG. 1A. As can be seen, the GSL, the SSL, and all of the word lines have the same bias voltages as shown in FIG. 1A. Likewise, the CS line 30 is grounded. However, the unselected bit line 32 is biased to a program-disturb voltage level of about VCC. This turns off the second switch, which corresponds with the SSL line, and decouples the semiconductor body in the region 35 from the unselected bit line BL 32. As a result, the semiconductor body in the region 35 is boosted by capacitive coupling from the voltages applied to the word lines 22-27. This boost disturbs the programming operation for the unselected memory string by preventing the formation of electric fields sufficient to disturb the charge trapped in the memory cells in the unselected NAND string. So-called incremental step pulsed programming ISPP operations based on capacitive self-boosting are common in the art.

While the programming operations described in connection with FIGS. 1A-1C can be effective, they are not without certain disadvantages. One problem is that such a high voltage level (e.g., 20-22 Volts) is needed for the programming voltage level V-PGM. This high voltage requirement imposes limitations on the design specifications for certain semiconductor structures of the memory device, making it difficult to continue to scale down the semiconductor structures.

Another issue is that conventional programming operations such as those described in connection with FIGS. 1A-1C only allow for a narrow voltage range for the program-disturb pass voltage V-PASS. On the one hand, if the pass voltage V-PASS is too low, there will be insufficient capacitive coupling to boost the semiconductor body on the unselected NAND strings, such as the one shown in FIG. 1B, which would disturb the memory cell (cell B in FIG. 1C) sharing a word line with the target memory cell (cell A in FIG. 1C). On the other hand, if the pass voltage V-PASS is too high, then hot carrier injection may occur in unselected memory cells (such as cell C in FIG. 1C) of the selected NAND string. As a result, the pass voltage V-PASS must be carefully controlled to be between these upper and lower boundaries. For example, a typical pass voltage V-PASS range is between 9 and 11 Volts. Such tight control can be difficult due to factors including process and environment variations.

Still another issue with such conventional programming operations is so-called gate induced drain leakage (GIDL) that can sometimes occur, for example at the junction between the ground select line GSL and the memory cell at word line WL0 and the. The GIDL phenomenon is difficult to avoid, and gets worse as devices are scaled down.

These and other disadvantages of prior NAND memory devices and programming operations can be overcome by employing devices and methods described herein. An improved NAND memory device can be achieved with NAND memory cells similar to those shown in FIGS. 1A and 1B, where each memory cell includes a charge trapping structure between doped source/drain regions. However, the presently-disclosed NAND memory cells are preferrably formed over a lightly doped substrate region, for example having a doping concentration that is less than or equal to 5×10¹² cm⁻², preferably greater than zero so that at least some light amount of doping is present. The lightly doped substrate will allow for inversion at lower voltage levels. Typically, the NAND memory cells will be N-type devices, although P-type devices are possible and can be implemented by those skilled in the art based on the present disclosure. Nevertheless, the present description will focus primarily on N-type devices. In N-type devices, the source/drain regions include N⁺ doped regions, for example formed as buried diffusion regions. In such cases, the light substrate doping is N⁻ type doping, so as to assist with electron inversion.

Also, memory devices and programming operations as disclosed herein allow for a reduced programming voltage level V-PGM, such that V-PGM can be less than or equal to 17 Volts. For example, programming voltage levels can be achieved in a range such as 13 Volts≦V-PGM≦17 Volts. In the devices and programming operations described herein, channel potential (Vch) is boosted up to 0.6×V-PGM or 0.7×V-PGM due to the extremely low substrate doping. For example, a programming voltage V-PGM of 13 Volts can boost the channel potential to around 7 or 8 Volts, which can induce hot-carrier injection into the storage node of the memory cell. As a result, a lower pass voltage V-PASS can also be used, for example in a range of 3 Volts≦V-PASS≦8 Volts, which also helps suppress GIDL. Also, the same pass voltage V-PASS can be used for programming and reading operations.

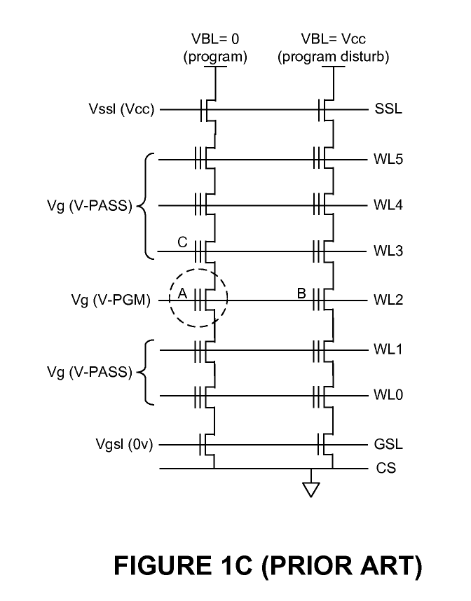

An embodiment of such a memory device is shown as a NAND flash memory device in FIGS. 2A and 2B. FIG. 2A shows in cross-section a plurality of dielectric charge trapping flash memory cells arranged in series to form a portion of a NAND string, and FIG. 2B shows a schematic view of NAND strings 101 and 103 that include memory cells as shown in FIG. 2A.

The NAND strings 101 and 103 can include first and second switches, corresponding to a ground select line (GSL) and a string select line (SSL), respectively, that are similar to those shown in FIGS. 1A and 1B, each being formed by a MOS transistor having a gate connected between a memory cell and a contact, where the contact is formed by an n-type region in the semiconductor body 10. In the case of the GSL, the contact can be connected to common source CS line; in the case of the SSL, the contact can be connected to a bit line BL. Referring to FIG. 2A, the memory cells can each be connected to a respective word line WL, such as word lines 23-25 shown in FIG. 2A. The memory cells can also each include a respective charge trapping structure 9 between the word lines WL and channel regions in the semiconductor body 10. For n-channel memory cells, the semiconductor body 10 can be an isolated p-well, within a deeper n-well in a semiconductor chip. Alternatively, the semiconductor body 10 can be isolated by an insulating layer or otherwise. Some embodiments may employ p-channel memory cells in which the doping for the semiconductor body would be n-type.

The plurality of flash memory cells is arranged in a string extending in a bit line direction, orthogonal to word lines. Word lines WL extend across a number of parallel NAND strings. Terminals, such as terminals 14 and 15 shown in FIG. 2A, are formed by n-type regions (for n-channel devices) in the semiconductor body 10, and act as the source/drain regions for the memory cells.

In this illustration, there are six memory cells in the string for simplicity. In typical implementations, a NAND string may comprise 16, 32, or more memory cells arranged in series. The memory cells corresponding to the word lines WL0-WL5 have charge trapping structures 9 between the word lines and channel regions in the semiconductor body 10.

Notably, the memory device shown in FIG. 2A can include a lightly doped substrate region 40 for easing the inversion of minority carriers, for example electrons in an n-channel device. In other words, the inversion process can occur at relatively lower voltage levels compared to prior devices that do not include the lightly doped substrate region 40. The lightly doped substrate region 40 can be doped according to the same conductivity type as the doping of the source/drain regions 14 and 15. For example, for an n-channel device, the lightly doped region 40 can be an n⁻ doped region. For embodiments that include a lightly doped region 40, the lightly doped region can have a doping concentration in a range of 0 cm⁻²≦doping concentration≦5×10¹² cm⁻². The lightly doped region 40 can be, for example, formed using known diffusion processes.

The charge trapping structures 9 in the memory cells can be dielectric charge trapping structures, floating gate charge trapping structures, or other flash memory structures suitable for programming using techniques described herein. Also, embodiments of NAND flash structures have been developed which are junction-free, where the terminals 13-17, and optionally terminals 12 and 18, may be omitted from the structure.

FIG. 2B shows a schematic view of a plurality of dielectric charge trapping flash memory cells arranged in series to form NAND strings 101 and 103 and biased for a programming operation according to the present disclosure. In FIG. 2B, memory string 101 is a selected memory string that includes a target cell (cell A) at word line WL2 for the programming operation. The memory string 103 is an unselected memory string connected to an unselected bit line BL1. Compared to FIG. 1C, it can be seen from the view shown in FIG. 2B that the program bit line and the program-disturb bitline voltages are opposite that of the conventional scheme shown in FIG. 1C.

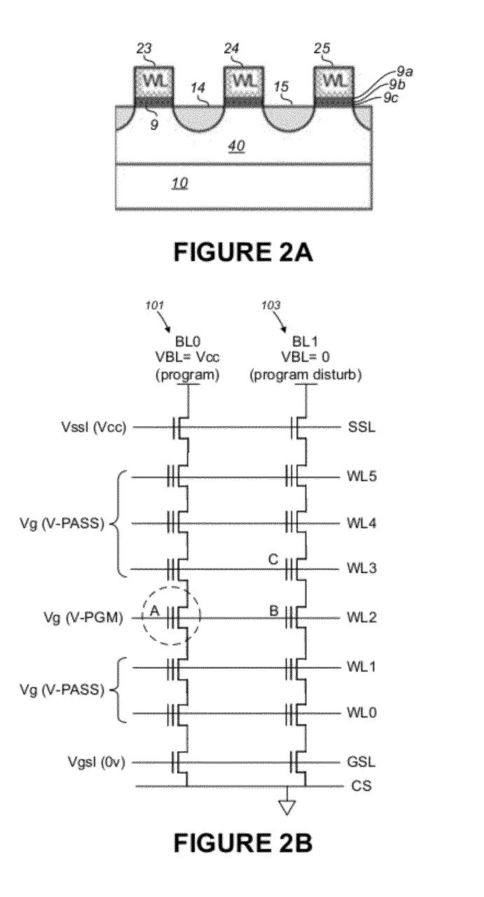

FIG. 3 shows a more detailed view of the voltage levels applied to the selected NAND string 101 for the programming operation associated with the view shown in FIG. 2B. More specifically, FIG. 3 shows unselected word line signal 105, selected word-line signal 106, SSL signal 107, and GSL signal 108. In order to program the target cell A, the unselected word line signal 105 is applied to the unselected word lines WL0, WL1, and WL3-WL5, the selected word line signal 106 is applied to the selected word line WL2, the SSL signal 107 is applied to the substrate from bit line BL0 through the SSL switch, and the GSL signal 108 is applied to the substrate from the CS line at the GSL switch.

At time t0, the NAND string 101 is at a ready state, with voltage levels of signals 105-108 all being set at 0 Volts. At or before time t1, a programming operation is initiated, for example by an internal command according to known memory control systems. In response, a voltage of about Vcc is applied to the SSL line, turning on the SSL switches, and a voltage of ≦0 Volts is applied to the GSL line, turning off the GSL switches, as shown in FIG. 2B. At time t1, the SSL signal 107 includes a set-up pulse 111 that is applied to the substrate of the selected NAND string 101 via bit line BL0. The set-up pulse 111 exceeds Vcc by some predetermined amount, such that Vt of SSL<Vcc<Pulse 111. The set-up pulse 111 creates a situation where a higher voltage is present at the drain of the SSL switch than at the gate, having the effect of attracting electrons into the channel regions—in other words, it initiates the inversion process in the selected string. Note that this effect does not occur in the unselected string 103, where 0 Volts is applied to the bit line BL1.

At time t2, when the programming voltage is applied to the selected word line WL2 for memory cell A, the hot electrons in or near the channel region for memory cell A are drawn into the charge trapping structure 9 of memory cell A. Note that the voltage levels shown in FIG. 3 are not drawn to scale, and so it will be appreciated that V-PGM>V-PASS. At time t2, the voltage V-PASS is applied to the unselected memory cells, but V-PASS is not strong enough to allow the hot electrons to overcome the energy barrier as required for being trapped in the charge trapping structures 9 of the unselected memory cells, such as cells B and C. Finally, at time t3, the voltage levels are all reduced back to 0 Volts and the programming operation is complete. Those skilled in the art will appreciate that some time between t2 and t3 can be selected to allow adequate time for the tunneling of the hot electrons into the charge trapping region 9, and can vary depending on several factors, for example device dimensions and materials.

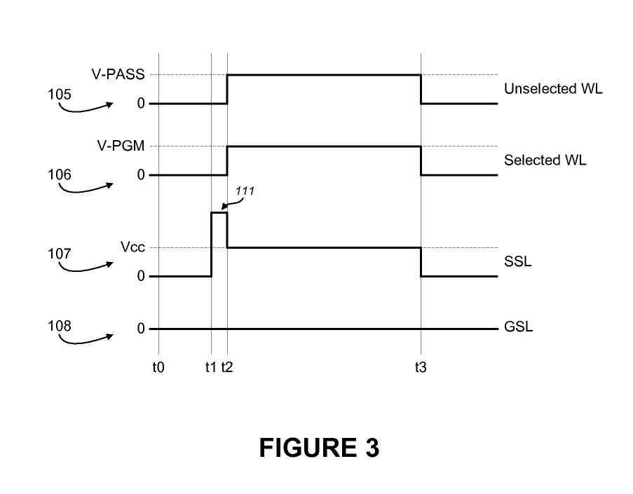

Turning next to FIGS. 4A and 4B, these charts illustrate examples of programming voltages and tunneling oxide thicknesses that can be used for specific implementations of the device shown in FIGS. 2A and 2B. For example, as shown in FIG. 4A, in some embodiments, a programming voltage of about 17 Volts can be used as V-PGM, and V-PASS can be in a range of about 7 Volts to about 13 Volts. As shown in FIG. 4A, a significantly greater number of electrons where injected into the charge trapping structure 9 of the selected memory cell A as compared to that of the unselected memory cell B.

The charge trapping structure 9 can include a tunneling oxide layer 9c directly over the substrate 10, or more specifically, directly over a lightly doped region 40 of the substrate 10. Then a floating gate (charge storage) layer 9b is provided directly over the tunneling oxide layer 9c. A blocking dielectric layer 9a is provided directly over the floating gate layer 9b. The control gate is provided directly over the blocking dielectric layer 9a. So, for example, the charge trapping structure 9 can be formed as a Silicon Oxide Nitride Oxide Silicon (SONOS) structure. However, other charge trapping structures can be used.

FIG. 4B illustrates the present programming operation advantageously allows for relatively thick tunneling oxide layer in such charge trapping structures 9 of the memory cells shown in FIGS. 2A and 2B. For example, the thickness T_{9c} of the tunneling oxide layer 9c can be in a range of 79 Angstroms to 91 Angstroms. Thicker tunneling oxide layers can require a slightly longer programming time (e.g., longer time between t2 and t3 in FIG. 3), so the preferable thickness T_{9c} is less than 90 Angstroms. However, memory cells having thicker tunneling oxide layers can benefit from relatively longer retention times, so other thicknesses are possible

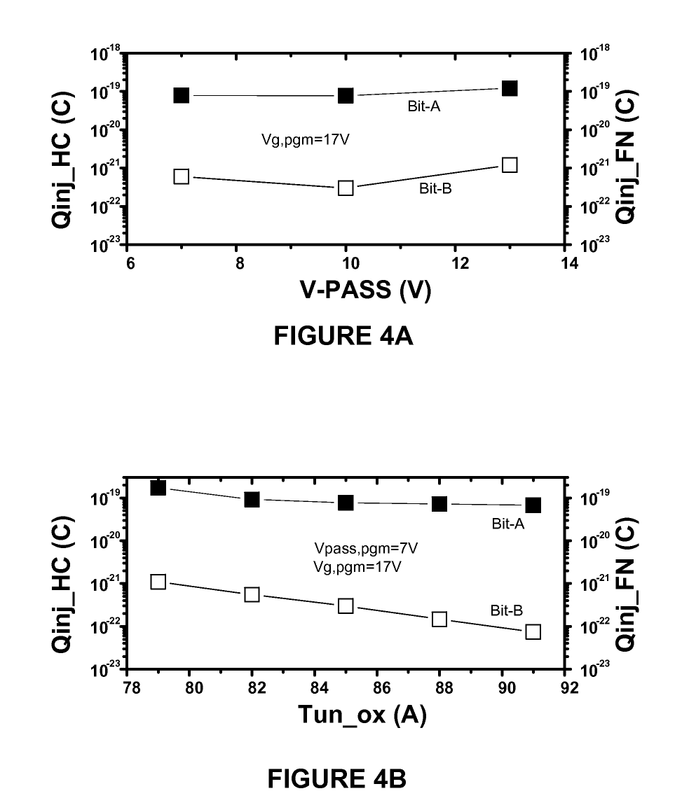

FIG. 5 shows a comparison of the WL0 disturbance for a conventional NAND memory string compared to that of the present memory device. As shown in FIG. 5, since the present NAND flash memory device can use lower voltage levels for V-PASS and V-PGM than those used for conventional NAND flash memory devices, the present NAND flash memory device benefits from a significant reduction in WL0 disturbance due to a lack of gate induced drain leakage (GIDL) sufficient to generate hot carriers in the region.

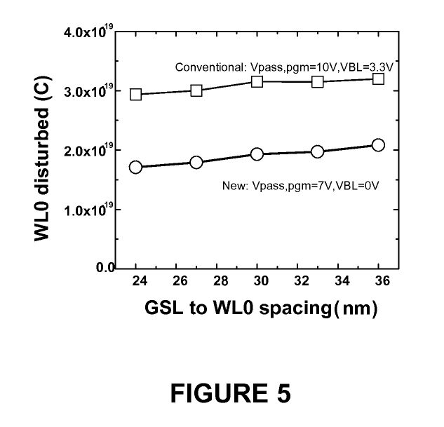

FIG. 6 shows an energy band diagram illustrating how the hot carrier injection occurs in the selected memory cell A during the presently disclosed programming operation. Note that FIG. 6 shows electron injection, as occurs for an N-channel device. Those skilled in the art will appreciate that hole injection instead occurs for a P-channel device. During the programming operation, the high SSL pulse 111 provides energy to electrons in the substrate 10, including those in the lightly doped region 40. Band to band tunneling accelerates the electrons, and the electrons become hot. The application of the programming voltage V-PGM attracts the hot electrons, providing sufficient energy to overcome the energy barrier at the tunneling oxide layer, so the hot electrons are injected into the floating gate layer FG.

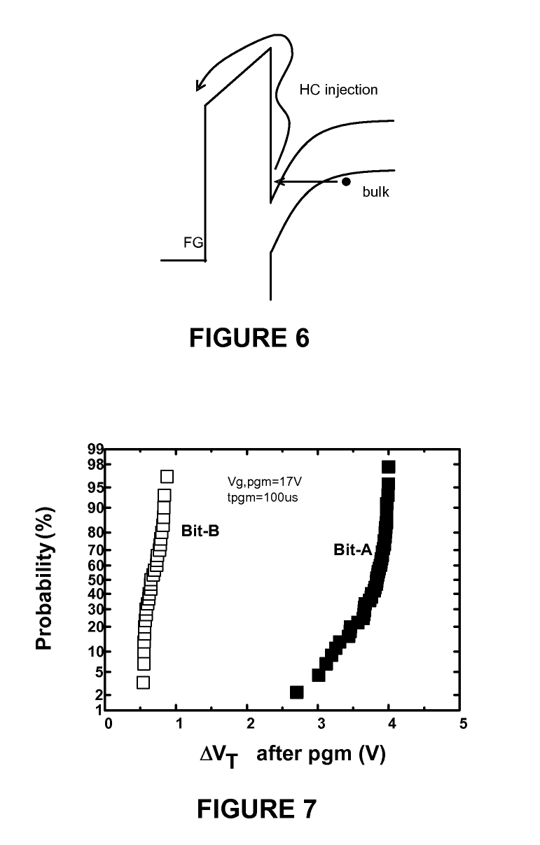

FIG. 7 shows the results of experimental data, illustrating how a sufficient difference in threshold voltages V_{T} can be achieved so as to allow for the determination of whether a memory cell is programmed or erased. For example, in FIG. 7, an erased memory cell B can be distinguished from a programmed memory cell A due to a difference in the respective threshold voltages of about 3.5 Volts.

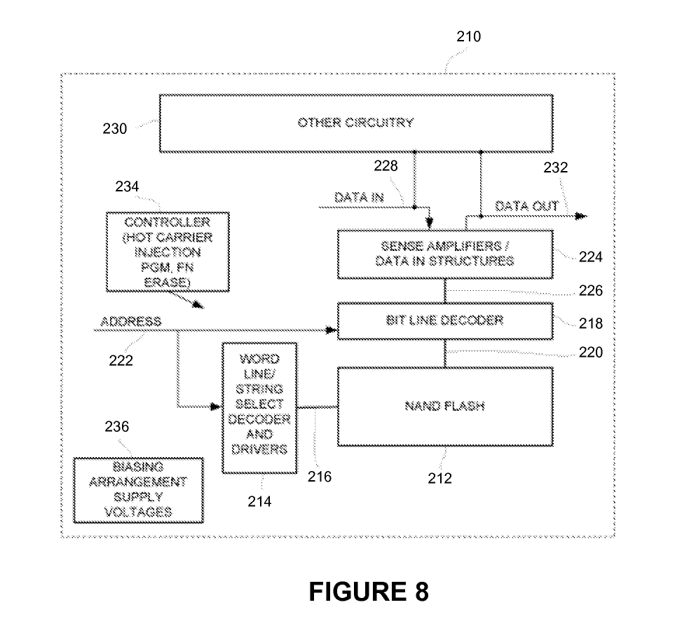

FIG. 8 is a simplified block diagram of an integrated circuit employing the hot carrier injection programmed NAND flash as described herein. The integrated circuit 810 includes a memory array 812 implemented using charge trapping memory cells or floating gate memory cells, for example, on a semiconductor substrate. A word line (or row) and string select decoder 814 (including appropriate drivers) are coupled to, and in electrical communication with, a plurality 816 of word lines, string select lines and ground select lines, arranged along rows in the memory array 812. A bit line (column) decoder and drivers 818 are coupled to and in electrical communication with a plurality of bit lines 820 arranged along columns in the memory array 812 for reading data from, and writing data to, the memory cells in the memory array 812. Addresses are supplied on bus 822 to the word line decoder and string select decoder 814 and to the bit line decoder 818. Sense amplifiers and data-in structures in block 824, including current sources for the read, program and erase modes, are coupled to the bit line decoder 818 via data bus 826. Data is supplied via the data-in line 828 from input/output ports on the integrated circuit 810 or from other data sources internal or external to the integrated circuit 810, to the data-in structures in block 824. In the illustrated embodiment, other circuitry 830 is included on the integrated circuit 810, such as a general purpose processor or special purpose application circuitry, or a combination of modules providing system-on-a-chip functionality supported by the memory cell array. Data is supplied via the data-out line 832 from the sense amplifiers in block 824 to input/output ports on the integrated circuit 810, or to other data destinations internal or external to the integrated circuit 810.

A controller 834 implemented in this example, using bias arrangement state machine, controls the application of bias arrangement supply voltages and current sources 836, such as read, program, erase, erase verify, program verify voltages or currents for the word lines and bit lines, and controls the word line/source line operation using an access control process. The controller implements the switching sequences used to induce boosted-node hot carrier programming as described herein. The controller 834 can be implemented using special purpose logic circuitry as known in the art. In alternative embodiments, the controller 834 comprises a general purpose processor, which may be implemented on the same integrated circuit, which executes a computer program to control the operations of the device. In yet other embodiments, a combination of special-purpose logic circuitry and a general-purpose processor may be utilized for implementation of the controller 834.

While various embodiments in accordance with the disclosed principles have been described above, it should be understood that they have been presented by way of example only, and are not limiting. Thus, the breadth and scope of the invention(s) should not be limited by any of the above-described exemplary embodiments, but should be defined only in accordance with the claims and their equivalents issuing from this disclosure. Furthermore, the above advantages and features are provided in described embodiments, but shall not limit the application of such issued claims to processes and structures accomplishing any or all of the above advantages.

Additionally, the section headings herein are provided for consistency with the suggestions under 37 C.F.R. 1.77 or otherwise to provide organizational cues. These headings shall not limit or characterize the invention(s) set out in any claims that may issue from this disclosure. Specifically and by way of example, although the headings refer to a “Technical Field,” such claims should not be limited by the language chosen under this heading to describe the so-called technical field. Further, a description of a technology in the “Background” is not to be construed as an admission that technology is prior art to any invention(s) in this disclosure. Neither is the “Summary” to be considered as a characterization of the invention(s) set forth in issued claims. Furthermore, any reference in this disclosure to “invention” in the singular should not be used to argue that there is only a single point of novelty in this disclosure. Multiple inventions may be set forth according to the limitations of the multiple claims issuing from this disclosure, and such claims accordingly define the invention(s), and their equivalents, that are protected thereby. In all instances, the scope of such claims shall be considered on their own merits in light of this disclosure, but should not be constrained by the headings set forth herein.

What is claimed is:

1. A memory comprising:
a plurality of memory cells arranged in series in a semiconductor body;
a plurality of word lines, each word line in the plurality of word lines being coupled to a respective one of the plurality of memory cells; and
control circuitry coupled to the plurality of word lines, the control circuitry being adapted for programming a selected memory cell in the plurality of memory cells corresponding to a selected word line by:
biasing one of first and second ends of the plurality of memory cells to a set-up voltage;
reducing the voltage level being applied to the one of the first and second ends of the plurality of memory cells from the set-up voltage to a bit-line programming voltage;
applying a pass voltage to word lines corresponding to unselected memory cells; and
applying a program voltage to the selected word line corresponding to the selected memory cell.

2. The memory of claim 1, wherein the semiconductor body includes a lightly doped substrate region.

3. The memory of claim 2, wherein the doping concentration of the lightly doped substrate is in a range that is less than or equal to 5×10¹² cm⁻².

4. The memory of claim 2, wherein the lightly doped substrate region includes an N⁻ type doped region.

5. The memory of claim 1, wherein each memory cell comprises a respective one of a plurality of charge trapping structures.

6. The memory of claim 5, wherein the charge trapping structures are formed over a lightly doped substrate region.

7. The memory of claim 5, wherein the charge trapping structures include respective tunnel dielectric layers each having a thickness that is less than 90 Angstroms.

8. The memory of claim 1, wherein the program voltage applied to the selected word line is less than or equal to 17 Volts.

9. The memory of claim 8, wherein the pass voltage is in a range of 3 Volts to 8 Volts.

10. The memory of claim 1, wherein the application of the set-up voltage causes inversion in the semiconductor body.

11. The memory of claim 1, wherein the biasing of one of first and second ends is performed during a first time period, and wherein the reducing of the voltage level, applying of the pass voltage, and applying of the program voltage are performed during a second time period following the first time period.

12. The memory of claim 1, wherein the biasing of one of first and second ends is performed while applying a ground level voltage to another of the first and second ends and to each of the plurality of word lines.

13. A memory comprising:
a first string of memory cells arranged in series in a semiconductor body;
a second string of memory cells arranged in series in the semiconductor body;
a plurality of word lines, each word line in the plurality of word lines being coupled to a respective one of the first string of memory cells and to a respective one of the second string of memory cells; and
control circuitry coupled to the plurality of word lines, the control circuitry being adapted for programming a selected memory cell in the first string of memory cells corresponding to a selected word line by:
applying a bit-line programming voltage to one of first and second ends of the first string of memory cells;
maintaining first and second ends of the second string of memory cells at a ground level voltage;
applying a pass voltage to word lines corresponding to unselected memory cells; and
applying a program voltage to the selected word line corresponding to the selected memory cell.

14. The memory of claim 13, wherein the semiconductor body includes a lightly doped substrate region.

15. The memory of claim 14, wherein the doping concentration of the lightly doped substrate is in a range that is less than or equal to 5×10¹² cm⁻².

16. The memory of claim 14, wherein the lightly doped substrate region includes an N⁻ type doped region.

17. The memory of claim 13, wherein each memory cell comprises a respective one of a plurality of charge trapping structures.

18. The memory of claim 17, wherein the charge trapping structures are formed over a lightly doped substrate region.

19. The memory of claim 17, wherein the charge trapping structures include respective tunnel dielectric layers each having a thickness that is less than 90 Angstroms.

20. The memory of claim 13, wherein the program voltage applied to the selected word line is less than or equal to 17 Volts.

21. The memory of claim 20, wherein the pass voltage is in a range of 3 Volts to 8 Volts.

22. The memory of claim 13, wherein the application of the set-up voltage causes inversion in the semiconductor body.

23. The memory of claim 13, wherein the control circuitry is further configured for, during a first time period, biasing the one of first and second ends of the first string of memory cells to a set-up voltage, while applying the ground level voltage to another of the first and second ends, to each of the plurality of word lines, and to both of the first and second ends of the second string of memory cells.

24. The memory of claim 23, wherein the applying of the bit-line programming voltage, the maintaining of the first and second ends at the ground level voltage, the applying of the pass voltage, and the applying of the program voltage are all performed during a second time period following the first time period.

25. The memory of claim 13, wherein the applying of the bit-line programming voltage includes reducing the voltage level being applied to the one of the first and second ends of the first string of memory cells from the set-up voltage to the bit-line programming voltage.
